(19) United States
(12) Patent Application Publication
(10) Pub. No.: US 2017/0244017 A1
(43) Pub. Date: Aug. 24, 2017

(54) ELECTRIC GENERATOR HAVING A THERMOELECTRIC GENERATOR

(71) Applicant: Hirschmann Automation and Control GmbH, Neckartenzlingen (DE)

(72) Inventors: Leo PETRAK, Marxzell (DE); Robert TORDY, Hasslock (DE); Martin WEIS, Karlsruhe (DE)

(21) Appl. No.: 15/502,724

(22) PCT Filed: Nov. 13, 2015
(86) PCT No.: PCT/EP2015/076600

§ 371 Date: Feb. 8, 2017

(30) Foreign Application Priority Data
Nov. 13, 2014 (DE) 10 2014 223 189.2

(51) Int. Cl. H01L 35/30

(52) U.S. Cl. CPC H01L 35/30

(57) ABSTRACT

An electric generator (1) comprises a thermoelectric generator (2) and is characterized in that said thermoelectric generator (2) is provided with two add-on units (3, 4) which are separate from each other, said two add-on units (3, 4) having different thermal properties.

### CROSS REFERENCE TO RELATED APPLICATIONS

This application is the US-national stage of PCT application PCT/EP2015/076600 filed 13 Nov. 2015 and claiming the priority of German patent application 102014223189.2 itself filed 13 Nov. 2014.

### FIELD OF THE INVENTION

The invention relates to an electric power supply having a thermoelectric generator.

### BACKGROUND OF THE INVENTION

Thermoelectric generators that utilize a temperature difference to generate electricity, are known in principle.

However these thermoelectric generators have the disadvantage of a low efficiency, so that, depending on the specific application, they cannot supply enough electricity for a consumer. However, in mobile applications, in particular in motor vehicles, in particular in working vehicles, there is a need to be independent of a separate vehicle power supply. Furthermore, there is a desire to avoid batteries that provide a power supply at a user's location and must be replaced.

### OBJECT OF THE INVENTION

The object of the present invention is therefore to improve the efficiency of a power supply device that uses a thermoelectric generator.

### SUMMARY OF THE INVENTION

This object is achieved according to the invention in that the thermoelectric generator that is known per se, is equipped with two separate add-on parts, and the two add-on parts have different thermal properties.

The basic idea is thus to use one or more thermoelectric generators in combination with at least two, preferably exactly two, bodies that are different with respect to their thermal properties. These bodies are structurally different with respect to their thermal capacity and the amount of heat uptake and/or heat release due to thermal radiation and convection over time. The goal is to map an outside temperature that changes over time in an environment, preferably the environment of use of the electric power supply and/or the vehicle, into a temperature difference ΔT that can be used by the thermoelectric generator. Due to the two separate add-on parts, the temperature difference acting on the thermoelectric generator is advantageously increased so as to increase the electric efficiency and therefore produce a greater amount of electric energy at the output of the thermoelectric generator.

### BRIEF DESCRIPTION OF THE INVENTION

Additional embodiments of the invention are described below and explained with reference to the figures of the drawing in which:

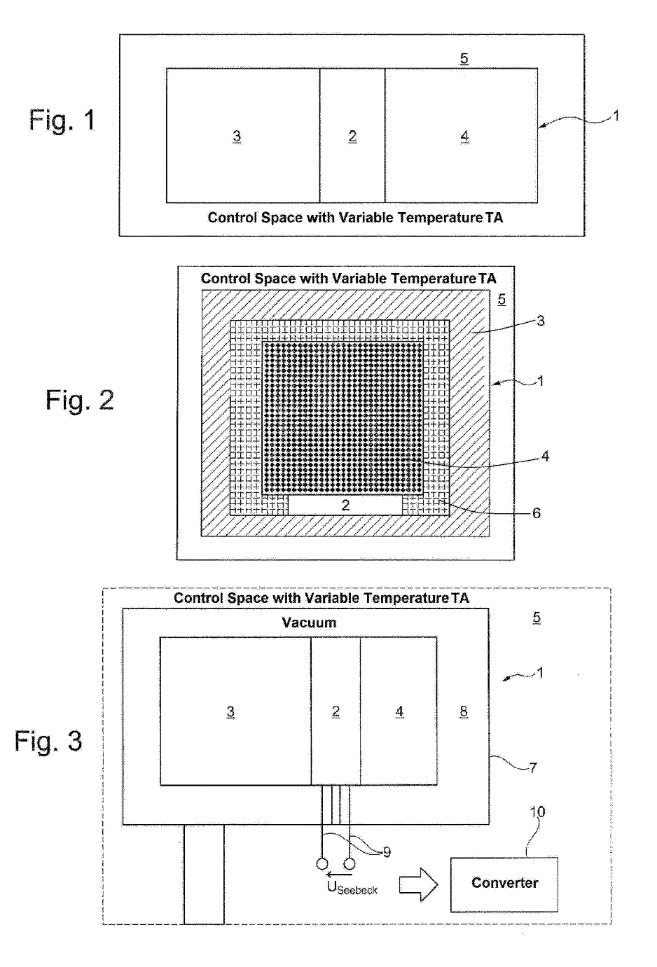

FIG. 1 is a simplified schematic view of a thermal generator according to the invention;

FIG. 2 is a schematic section through the thermogenerator of the invention;

FIG. 3 is a schematic view somewhat more detailed than FIG. 1 of the power supply of the instant invention;

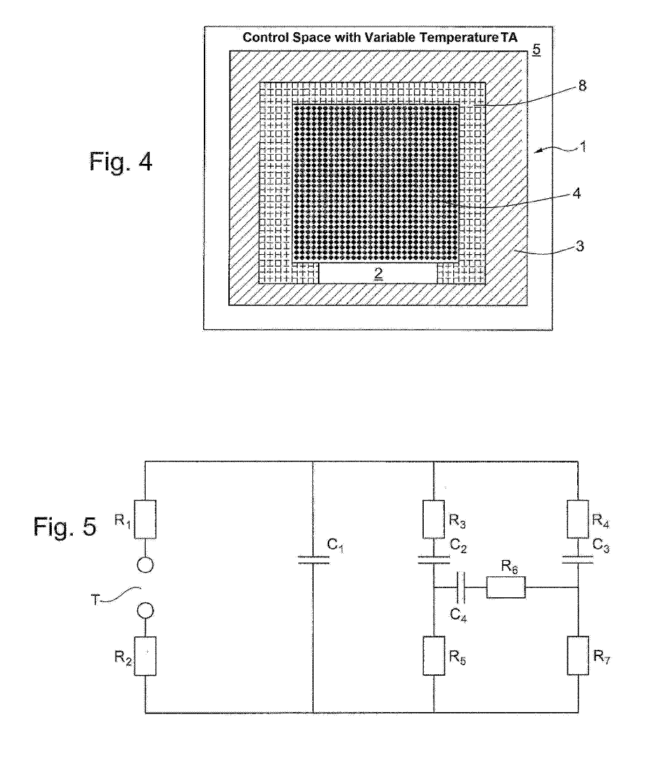

FIG. 4 is a view like FIG. 2 of a variant of this invention; and

FIG. 5 is a circuit diagram of the instant invention.

### SPECIFIC DESCRIPTION OF THE INVENTION

FIG. 1 shows in a schematic diagram, which is detailed in this regard, an electric power supply 1 that uses a thermoelectric generator 2 that is known per se. This thermoelectric generator 2 has a hot side and a cold side. A first add-on part 3 is on one side and a second add-on part 4 is on the other side, so that these two parts 3, 4 are preferably affixed to the face on the hot side and the face on the cold side of the thermoelectric generator 2. This electric power supply 1, which is shown in FIG. 1, is in an environment 5 in which it is at the area of operation of the electric power supply 1 but also around a closed control space in which a variable outside temperature TA prevails.

FIG. 2 shows that an insulator 6 is between the add-on parts 3, 4. This is a mutually interconnected arrangement, and the add-on part 3 contains both the thermoelectric generator 2 and the add-on part 4. The add-on part 4 is thus disposed inside the insulator 6 that is in turn disposed inside the add-on part 3, so that the two add-on parts 3, 4 are connected by a thermal insulator.

FIG. 3 shows the schematic diagram of an electric power supply 1 having a design similar to that shown in FIG. 1. In addition, the thermoelectric generator 2 with its add-on parts 3, 4 is inside a housing 7. The housing 7 is in turn located in the environment and/or in the above-mentioned control space. Inside the housing 7, the elements disposed therein are in a vacuum. The thermoelectric generator 2 has electric terminals 9 that extend out of the housing 7 and at which a voltage with improved electric efficiency is made available according to the Seebeck effect (U_{Seebeck}). The electric power supply 1 is connected to a converter, in particular a DC-DC converter, via the electric terminals 9. At the output of the electric terminals 9 and/or at the output of the converter 10, a power supply for mobile applications with an increased efficiency is thus available.

FIG. 4 shows another specific embodiment of the electric power supply 1. A vacuum 8 is between the add-on parts 3, 4, such that the add-on part 4 on the thermoelectric generator 2 is surrounded by the vacuum 8 and the latter is in turn inside the add-on part 3. Thus the add-on part 3 with its outer surface forms a type of housing, so that the electric power supply 1 is in the environment 5 or inside the control space.

FIG. 5 shows a schematic diagram of the electric power supply 1 according to the invention. The meaning of the individual electronic parts in this schematic diagram and their dimensions are shown in the following table.

| Part | Corresponds to | Electric part class, size |
|---|---|---|
| C₁ | Thermal Capacity - Housing | Small |
| C₂ | Thermal Capacity - Transformer 1 | Small |
| C₃ | Thermal Capacity - Transformer 2 | Large |
| C₄ | Thermogenerator | (ideal small - design |
| | | dependent) |
| R₁ R₂ | Heat Transfer - Environment/Housing | Small to average |
| R₃ R₅ | Heat Transfer - Housing/Trans. 1 | Small |
| R₄ R₇ | Heat Transfer - Housing/Trans 1 | Large |
| R₆ | Heat transfer - Thermogenerator | Thermally large, |
| | | electrically small to |
| | | average |

The dimensions are to be selected so that
C₁, including the respective resistors, filters out short-term fluctuations due to variable incident sunlight,
C₄ is large enough to always be colder than C₂ throughout the day (including dimensions of resistors R₃, R₄, R₅ and R₇) and ideally to be warmer than C₂ at night (reversal of voltage must be provided in the DC-DC converter through the circuitry),
R₆ is great enough thermally for the first condition to be able to function and to yield favorable conversion rates electrically with respect to the DC-DC converter (efficiency of energy conversion from thermal to electric and the voltage conversion),
Add-on and connection technology for the thermal generator to the DC-DC converter,
Vacuum technology for the implementation of electric terminals in particular,
Suitable materials for the heat transfer medium and the housing (emission, thermal capacity, thermal conductivity),
Insulation materials for mounting the structure in the vacuum container as well as the container on the ambient construction.

The two add-on parts 3, 4 may have any geometric shapes, for example, square, rectangular, triangular, round, oval or comparable shapes. It is necessary to ensure that each add-on part 3, 4 is brought into surface contact with the respective face of the thermoelectric generator 2 and that a very good thermal connection is ensured in the area of this contact surface for the purpose of adequate and/or secure heat transfer.

The heat flow Q′ emitted by a body can be calculated as follows using the Stefan-Boltzmann law:

Q′=∂Q/∂t=εσAT⁴

where
Q′: Heat flow and/or radiation power
ε: Emission: These values are between 0 (perfect mirror) and 1 (ideal black body)
σ=5.67 10⁻⁸ W/m²K⁴: Stefan-Boltzmann constant
A: Surface area of the emitting body
T: Temperature of the emitting body (in Kelvin)

The heat flow Q′ emitted by a body can be calculated as follows using the Stefan-Boltzmann law:

Q′=∂Q/∂t=εσAT⁴

where
Q′: Heat flow and/or radiation power
ε: Emission: These values are between 0 (perfect mirror) and 1 (ideal black body)
σ=5.67 10⁻⁸ W/m²K⁴: Stefan-Boltzmann constant
A: Surface area of the emitting body
T: Temperature of the emitting body (in Kelvin)
   Is independent of the ambient medium,
   In a vacuum, there is only this mechanism for heat transfer, i.e., the two heat transfer bodies have no possibility of exchanging energy (heat)
      ΔT outside of the thermoelectric generator.

1. An electric power supply having a thermoelectric generator, wherein the thermoelectric generator is equipped with two separate add-on parts that have different thermal properties.

2. The electric power supply according to claim 1, further comprising:
an insulator between the add-on parts.

3. The electric power supply according to claim 1, further comprising:
a vacuum is between the add-on parts.

4. The electric power supply according to claim 1, wherein the add-on part is inside the add-on part.

5. The electric power supply according to claim 1, further comprising:
a housing containing the thermoelectric generator together with the two separate add-on parts.

6. The electric power supply according to claim 5, further comprising:
a vacuum in the housing.
